(19) United States
(12) Patent Application Publication
(10) Pub. No.: US 2014/0319464 A1
(43) Pub. Date: Oct. 30, 2014

(54) LIGHT RECEIVING ELEMENT AND METHOD FOR MANUFACTURING SAME

(71) Applicant: Yasuhiro Iguchi, Yokohama-shi (JP)

(72) Inventor: Yasuhiro Iguchi, Yokohama-shi (JP)

(21) Appl. No.: 14/365,515

(22) PCT Filed: Jun. 11, 2012
(86) PCT No.: PCT/JP2012/064864

§ 371 Date: Jun. 13, 2014

(30) Foreign Application Priority Data
Dec. 14, 2011 (JP) 2011-273572

(51) Int. Cl. H01L 31/0216; H01L 31/18; H01L 31/0224; H01L 31/109; H01L 31/0352

(52) U.S. Cl. CPC H01L 31/02161; H01L 31/109; H01L 31/035236; H01L 31/022408; H01L 31/18
USPC 257/21; 438/98

(57) ABSTRACT

A light-receiving element includes a light-receiving layer for receiving light, the light-receiving layer being disposed on a semiconductor substrate, a contact layer disposed on the light-receiving layer, and a pixel electrode that is in ohmic contact with the contact layer. A back surface of the semiconductor substrate functions as a light-incident surface, and a reaction-preventing film for preventing a chemical reaction between the contact layer and the pixel electrode is interposed in a predetermined region between the contact layer and the pixel electrode.

### TECHNICAL FIELD

The present invention relates to a light-receiving element, a method for manufacturing the light-receiving element, and an optical device including the light-receiving element. More specifically, the present invention relates to a light-receiving element having a high sensitivity in the near-infrared to far-infrared region, a method for manufacturing the light-receiving element, and an optical device including the light-receiving element.

### BACKGROUND ART

A type-II multi-quantum well (MQW) structure of III-V compound semiconductors has become the most commonly used technology for light-receiving elements that have a sensitivity in the near-infrared region to the far-infrared region. For example, in the case of a type-II (InGaAs/GaAsSb) MQW structure, when light is received, an electron transits from the valence band GaAsSb having a large band gap energy to the conduction band of InGaAs over the Fermi level. As a result, an electron-hole pair is generated as a whole from a hole generated in the valence band of GaAsSb and an electron generated in the conduction hand of adjacent InGaAs by receiving light. During receiving the light, a reverse bias voltage is applied to a p-n junction or a p-i-n junction. Thus, an electron flows to an n-side electrode, usually, to the ground electrode side, and a hole flows to a p-side electrode, usually, to the pixel electrode side. Then, hole is read out to the pixel electrode. When pixels are two-dimensionally arrayed and light is incident from a back surface of a substrate in an epitaxial-layer mounting that is usually used, the light is received in a light-receiving layer disposed near a light-incident surface. Therefore, holes, which are heavier than electrons, move to a pixel electrode through a rising and falling potential barrier of an MQW over a long distance. Accordingly, annihilation of carriers (holes) occurs in moving to the pixel electrode and most of carriers (holes) cannot reach the pixel electrode. The light-receiving sensitivity decreases accordingly. The light-receiving sensitivity of the light-receiving element having a type-II MQW structure is originally low because transition of electrons (carriers) occurs between layers adjacent to each other. The light-receiving sensitivity is further decreased by such a annihilation of carriers (holes).

In order to improve the sensitivity, an anti-reflection film is formed on a light-incident surface, for example. However, a significant improvement that eliminates the problem is not obtained. Furthermore, regarding an image sensor, a structure including microlenses arranged for respective light-receiving elements has been proposed in order to increase the utilization efficiency of light, that is, in order to increase the light-receiving sensitivity. In addition, a method for increasing a light collection efficiency has been proposed in which reflection is suppressed by forming a resin layer serving as an underlying layer of a lens on a sensor, and forming a microlens composed of a resin on the resin layer so as to have fine concavoconvex portions on the surface of the microlens, for example (PTL 1).

### CITATION LIST

### Patent Literature

PTL 1: Japanese Unexamined Patent Application Publication No. 2009-116056

### SUMMARY OF INVENTION

### Technical Problem

However, the microlens array including a resin layer serving as an underlying layer has a problem in that light is absorbed by a resin and the light-receiving sensitivity in a specific wavelength band may be degraded. In addition, the formation of the microlenses requires a mold, resulting in an increase in the production cost.

An object of the present invention is to provide a light-receiving element which has a high sensitivity and whose cost for increasing the sensitivity is not substantially increased, a method for manufacturing the light-receiving element, and an optical device including the light-receiving element.

### Solution to Problem

A light-receiving element according to the present invention is a light-receiving element formed on a semiconductor substrate and including a pixel. The light-receiving element includes a light-receiving layer for receiving light, the light-receiving layer being disposed on the semiconductor substrate; a contact layer disposed on the light-receiving layer; and a pixel electrode that is in ohmic contact with the contact layer. A back surface of the semiconductor substrate functions as a light-incident surface. In addition, a reaction-preventing film for preventing a chemical reaction between the contact layer and the pixel electrode is interposed in a limited region between the contact layer and the pixel electrode.

The reaction-preventing film is transparent to light in a wavelength region which is selected as a light reception target of the light-receiving element. In general, when a pixel electrode is brought into ohmic contact with a contact layer, heat treatment is performed in a state where the pixel electrode and the contact layer are in contact with each other. In this case, the pixel electrode chemically reacts with the contact layer and has a rough surface. Since the electrode has a rough surface which is significantly different from a smooth metal surface which is particular to a metal, ohmic contact can be established. As a result, even when light incident from a back surface of a semiconductor substrate reaches the surface that establishes the ohmic contact, the light is, for example, diffusely reflected and the reflected light cannot be used for light reception of the light-receiving element. In contrast, in the region of the electrode where the reaction-preventing film is interposed, a chemical reaction with the contact layer is prevented, and thus a smooth or substantially smooth metal surface is maintained. Consequently, light reaching the hack surface of the electrode through the reaction-preventing film is reflected by the electrode back surface serving as a reflection surface and returned to the light-receiving layer of the light-receiving element. As a result, in the return path after reflection, the light is again provided with a chance to be received by the light-receiving layer. Thus, the light-receiving sensitivity can be improved.

Herein, the term “limited region” refers to a region remaining after an ohmic contact region is secured, that is, the term “limited region” does not mean the entire region where the pixel electrode overlaps with the contact layer.

Note that the reaction-preventing film does not necessarily completely prevent a chemical reaction between the pixel electrode and the contact layer, and may be a film that substantially suppresses a chemical reaction. In short, it is sufficient that the reaction-preventing film can reflect at least part of light and return the light to the light-receiving layer. The pixel electrode is located on an upper surface of an epitaxial layer (a surface farther than an epitaxial layer when viewed from the semiconductor substrate), and may be referred to as an “upper electrode” under the assumption that the semiconductor substrate is located on a lower side. The light-receiving element may include a single pixel. Alternatively, the light-receiving element may be a light-receiving element array in which a plurality of pixels are one-dimensionally or two-dimensionally arrayed.

In the light-receiving element of the present invention, a region of the pixel electrode in contact with the contact layer is located in a whole peripheral portion of the pixel electrode that is in contact with the reaction-preventing film, or a part of the peripheral portion.

With this structure, while a substantially central portion of the pixel electrode is used as a reflection surface, a region where ohmic contact is established is located in the peripheral portion and the region for forming the ohmic contact having a large area can be easily obtained. Therefore, the electrical resistance can be decreased. Furthermore, since a substantially central portion of the pixel electrode function as a reflection surface, the reflected light is returned to the light-receiving layer while decreasing the proportion of loss of the reflected light.

The light-receiving element of the present invention may further include a protective film that covers at least the contact layer around the pixel electrode. In addition, the reaction-preventing film may have a thickness smaller than a thickness of the protective film.

The reaction-preventing film is often formed by using a material that is the same as or similar to the material of the protective film (passivation film). The protective film needs to have a thickness of a predetermined value or more for blocking moisture, for example. In contrast, the reaction-preventing film preferably has a small thickness because it is sufficient that the reaction-preventing film can prevent a chemical reaction only during heat treatment. When the reaction preventing film has a small thickness, it is possible to reduce the length of a portion that is extended so that the pixel electrode contacts the contact layer. Therefore, the minimum contact between the pixel electrode and the contact layer is easily secured.

In the light-receiving element of the present invention, the reaction-preventing film is preferably at least one of a silicon nitride (SiN) film, a silicon oxynitride (SiON) film, and a silicon oxide (SiO₂) film.

The above material is also used in the protective film (passivation film). When the above material is interposed between the pixel electrode and the contact layer, a chemical reaction between the pixel electrode and the contact layer can be prevented or suppressed. During the heat treatment for establishing ohmic contact, the pixel electrode is in contact with the reaction-preventing film without being in contact with the contact layer, and thus the pixel electrode can maintain a smooth or substantially smooth metal surface. The material of the reaction-preventing film is transparent to light in the near-infrared to fare infrared region. Regarding light incident from the back surface of the semiconductor substrate, the back surface functioning as a light-incident surface, part of the light is received when passing through the light-receiving layer. The light that has not been received passes from the contact layer through the reaction-preventing film and reaches the pixel electrode. Since the pixel electrode (back surface) maintains a smooth metal surface as described above, the pixel electrode (back surface) functions as a reflection surface, reflects the reached light, and returns the light to the light-receiving layer. Thus, a chance to be received by the light-receiving layer can be enhanced. Since the material of the reaction-preventing film is commonly used in this field, the reaction-preventing film can be easily formed.

In the light-receiving element of the present invention, the light-receiving layer may have a p-n junction therein or the light-receiving layer may include therein an insertion layer having a bottom of the conduction band higher than a bottom of the conduction band of the light-receiving layer.

With this structure, for a p-i-n photodiode and an element including a light-receiving layer having an n-B-n (n-type layer/barrier layer/n-type layer) structure, the light-receiving sensitivity can be improved by disposing the reaction-preventing film.

In the light-receiving element of the present invention, the light-receiving layer may have a type-II multi-quantum well (MQW) structure.

In a type-II MQW structure, when light is received, an electron transits, over the Fermi level, from the valence band of a layer having a high band gap energy to the conduction band of another layer having a low band gap energy, the layer having the high band gap energy and the layer having the low band gap energy forming a pair. At this time, an electron hole pair is generated. The difference in the energy at the time of the transition becomes smaller than that in the transition from the valence band to the conduction band in the same layer. Thus, light reception can be performed on the long-wavelength side, that is, in the near-infrared to far-infrared region. In the case of the type-II MQW structure, the sensitivity can be extended to the long-wavelength side in this manner. However, since the transition to an adjacent layer is used, the sensitivity is originally low and this is a shortcoming of the type-II MQW structure. By arranging the reaction-preventing film described above, a chance to be received by the light-receiving layer is provided not only to light in an outgoing path but also to light in the return path after reflection. The arrangement of the reaction-preventing film can significantly contribute to the type-II MQW structure, which has a disadvantage of a low sensitivity.

An optical device of the present invention includes any of the light-receiving elements described above.

With this structure, it is possible to provide an optical device having a high light-receiving sensitivity, in particular, having a high light-receiving sensitivity in the near-infrared to far-infrared region,

A method for manufacturing a light-receiving element of the present invention is a method for manufacturing a light-receiving element formed on a semiconductor substrate and including a pixel. The method includes the steps of forming a light-receiving layer on the semiconductor substrate; forming a contact layer on the light-receiving layer; limitedly providing a reaction-preventing film so as to be in contact with the contact layer in a region which serves as a front surface of the pixel and on which a pixel electrode is to be provided; depositing a pixel electrode layer that covers the contact layer so as to cover the reaction-preventing film and extend over the region of the reaction-preventing film; and conducting heat treatment so that the electrode layer and the contact layer chemically react each other to establish ohmic contact in a region where the electrode layer contacts the contact layer.

By employing the above method, a reaction-preventing film can be interposed in a limited region between a contact layer and a pixel electrode by using a material that is commonly used and without substantially adding a special step. Herein, the phrase “limitedly providing a reaction-preventing film” refers to the same meaning of the “limited region” described above and means that the reaction-preventing film is provided in a region remaining after an ohmic contact region is secured, that is, the reaction-preventing film is provided in a region that is not the entire region where the pixel electrode overlaps with the contact layer.

Before the reaction-preventing film is provided, a protective film that covers at least a region of the contact layer, the region being other than the region on which the pixel electrode is to be provided, may be formed. The entire surface may be subsequently covered with a layer of the anti-reflection film. The reaction-preventing film may be subsequently limitedly formed by etching using a resist pattern as a mask. The electrode layer that covers the reaction-preventing film and the contact layer may be subsequently deposited.

By employing the above method, both the ensuring of ohmic contact of the pixel electrode and the maintenance of a smooth metal surface of the back surface of the pixel electrode can be easily realized by using a material that is commonly used and without substantially adding a special step.

In the case where a planar-type light-receiving element is produced, after the contact layer is first formed and before the reaction-preventing film is formed, a selective diffusion mask pattern may be formed. An impurity may be subsequently selectively diffused from an opening of the selective diffusion mask pattern under heating. When the reaction-preventing film is subsequently limitedly provided, the entire surface may be first covered with a layer of the reaction-preventing film, and a resist pattern may be subsequently formed so that a region where the reaction-preventing film is to be formed is covered with a covering portion of the resist pattern. A portion other than the covering portion of the resist pattern may be subsequently removed by etching. Thus, the reaction-preventing film can be limitedly formed.

The material that forms the selective diffusion mask pattern is usually changed by heating for selective diffusion, and consequently, has a property of not being easily etched. That is, as a result of the selective diffusion under heating, it becomes difficult to etch the selective diffusion mask pattern. Therefore, when an unnecessary portion is removed by etching for the reaction-preventing film, only a portion of the reaction-preventing film that covers the selective diffusion mask pattern can be easily removed and the selective diffusion mask pattern disposed under the reaction-preventing film may be hardly etched. As a result, the reaction-preventing film can be limitedly formed relatively easily. The selective diffusion mask pattern is left as it is and used as a protective film (passivation film).

In the case where a light-receiving element having a mesa structure is produced, after the contact layer is formed and before the reaction-preventing film is formed, a mesa structure may be formed by providing a groove by etching so as to surround a region where the pixel electrode is to be formed. Next, a protective layer that covers a region of the contact layer, the region being other than the region on which the pixel electrode is to be provided, and a side surface of the groove of the mesa structure may be subsequently formed. When the reaction-preventing film is subsequently limitedly provided, the entire surface may be first covered with a layer of the reaction-preventing film. A resist pattern may be subsequently formed so that a region where the reaction-preventing film is to be formed is covered with a covering portion of the resist pattern. A portion other than the covering portion of the resist pattern may be subsequently removed by etching. Thus, the reaction-preventing film can be limitedly formed.

### Advantageous Effects of invention

According to the present invention, it is possible to obtain a light-receiving element which has a high sensitivity and whose cost for increasing the sensitivity is not substantially increased, a method for manufacturing the light-receiving element, and an optical device including the light-receiving element.

### BRIEF DESCRIPTION OF DRAWINGS

FIG. 1A shows a light-receiving element according to Embodiment 1 of the present invention, and is a cross-sectional view.

FIG. 1B shows a light-receiving element according to Embodiment 1 of the present invention, and is a partially enlarged view of the structure of contact layer/reaction-preventing film/pixel electrode,

FIG. 2 is a view showing an energy band of a type-II MQW of the light-receiving element shown in FIG. 1.

FIG. 3 shows a production method, part A is a view showing a step of selectively diffusing zinc (Zn) from an opening of a selective diffusion mask pattern 36, part B is a view showing a step of depositing a layer 8a of a reaction-preventing film, part C is a view showing a step of forming a reaction-preventing film 8 by selective etching, part D is a view showing a step of depositing a metal layer of a pixel electrode 11 and performing heat treatment for establishing ohmic contact, and part E is a view showing a step of forming a ground electrode 12 and an anti-reflection film 35 on a back surface of a substrate.

FIG. 4 is a plan view of a back surface of a pixel electrode of the light-receiving element shown in FIG. 1.

FIG. 5A shows a light-receiving element according to Embodiment 2 of the present invention, and is a view showing a case where both a lower layer 3c of a light-receiving layer 3 and a buffer layer 2 are provided.

FIG. 5B shows a light-receiving element according to Embodiment 2 of the present invention, and is a view showing a case where only a lower layer 3c of a light-receiving layer 3 is provided and a buffer layer 2 is not provided.

FIG. 6A shows a light-receiving element according to Embodiment 3 of the present invention, and is a view showing a case where both a lower layer 3c of a light-receiving layer and a buffer layer 2 are provided.

FIG. 6B shows a light-receiving element according to Embodiment 3 of the present invention, and is a view showing a case where only a lower layer 3c of a light-receiving layer is provided and a buffer layer 2 is not provided.

FIG. 7A shows a light-receiving element and an optical device according to Embodiment 4 of the present invention, and is a cross-sectional view.

FIG. 7B shows a light-receiving element and an optical device according to Embodiment 4 of the present invention, and is a partially enlarged view.

FIG. 7C shows a light-receiving element and an optical device according to Embodiment 4 of the present invention, and is a plan view of a back surface of pixel electrodes.

### REFERENCE SIGNS LIST

1 substrate, 2 buffer layer, 3 light-receiving layer, 3a upper layer of light-receiving layer, 3b middle layer of light-receiving layer, 3c lower layer of light-receiving layer, 4 diffusion concentration distribution adjusting layer, 5 contact layer, 6 p-type region, 8 reaction-preventing film, 8a layer of reaction-preventing film, 10 light-receiving element, pixel electrode, 12 ground electrode, 15 p-n junction, 19 bump, 35 anti-reflection film, 36 selective diffusion mask pattern, 37 passivation film, 50 optical device, 70 read-out integrated circuit, 71 read-out electrode, 79 bump, J concavo-convex region, K metal surface (back surface), P pixel.

### DESCRIPTION OF EMBODIMENTS

### Embodiment 1

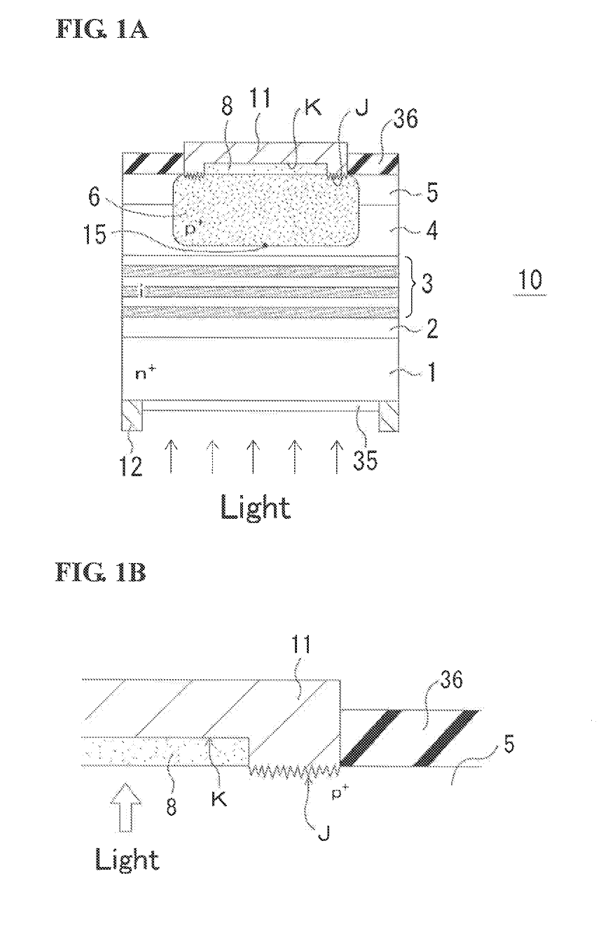

FIGS. 1A and 1B show a light-receiving element 10 according to an embodiment of the present invention. FIG. 1A is a cross-sectional view of the light-receiving element 10. FIG. 1B is an enlarged view of a part in which contact layer 5/reaction-preventing film 8/pixel electrode 11/selective diffusion mask pattern 36 are closely disposed. An epitaxial stacked layer including buffer layer 2/light-receiving layer 3 having type-II (GaAsSb/InGaAs) MQW structure/diffusion concentration distribution adjusting layer 4/InP contact layer 5 is formed on a substrate 1 composed of InP. The light-receiving element 10 of the present embodiment is a planar-type p-i-n photodiode. A p-type region 6 is formed by selectively diffusing Zn which is a p-type impurity through an opening of the selective diffusion mask pattern 36, and a p-n junction 15 is formed in the diffusion front of the p-type region 6. The mask pattern 36 used in the selective diffusion is just left without being removed and functions as a protective film. The pixel electrode 11 is in ohmic contact with the p-type region 6 of the contact layer 5. A ground electrode 12 that form a pair with the pixel electrode 11 is in ohmic contact with a back surface of the n-type InP substrate 1. The back surface of the InP substrate 1 is a light-incident surface. An anti-reflection (AR) film 35 is disposed on the back surface of the InP substrate 1.

<Points of the Present Invention>

A feature of the present invention lies in that the reaction-preventing film 8 is disposed in a limited region between the contact layer 5 and the pixel electrode 11 while the pixel electrode 11 is brought into ohmic contact with the p-type region 6 of the contact layer 5. As shown in FIG. 1B, the ohmic contact between the pixel electrode 11 and the p-type region 6 of the contact layer 5 is formed at the interface between the pixel electrode 11 and the p-type region 6. This interface is formed as follows. After forming the pixel electrode 11 composed of AuZn, TiPt, for example, heat treatment (for example, at 340° C. for one minute in a nitrogen atmosphere) is performed for forming ohmic contact. At the interface, a chemical reaction proceeds as a result of the heat treatment, and projections having an anchor shape or a dendritic shape are formed in the p-type region 6, thus forming a significantly rough surface. In other words, by forming this rough surface, ohmic contact is formed. A region J having the significantly rough surface on which the projections having an anchor shape or a dendritic shape are formed does not function as a reflection surface that reflects light.

A back surface K of the pixel electrode 11 is also shown in FIG. 1B. Since the reaction-preventing film 8 is arranged, the back surface K of the pixel electrode 11 does not contact the p-type region 6 of the contact layer 5 but contacts the reaction-preventing film 8. The reaction-preventing film 8 is formed of at least one of a silicon nitride (SiN) film, a silicon oxynitride (SiON) film, and a silicon oxide (SiO₂) film. The reaction-preventing film 8 does not substantially react with, for example, AuZn or Pt/Ti which constitutes the pixel electrode 11. Alternatively, the reaction-preventing film 8 suppresses a chemical reaction and suppresses the formation of the rough surface. Therefore, the back surface K of the pixel electrode 11 may maintain a smooth or substantially smooth metal surface K. This smooth metal surface K functions as a reflection surface to light. Furthermore, the SiN film, the SiON film, or the SiO₂ film is transparent to light in the near-infrared to far-infrared region.

Light incident on the back surface of the InP substrate 1, the back surface functioning as a light-incident surface, is first received in the light-receiving layer 3. The intensity of light is decreased in accordance with absorption of light in the light-receiving layer 3. However, a relatively large proportion of light is not absorbed and remains. The light that is not absorbed passes from the light-receiving layer 3 through the diffusion concentration distribution adjusting layer 4, the contact layer 5, and the transparent reaction-preventing film 8 described above, and reaches the metal surface K. Since the metal surface K functions as a reflection surface, the light reaching the metal surface K is reflected by the metal surface K and returned to the light-receiving layer 3. Accordingly, the light passes through the light-receiving layer 3 not only in the outgoing path but also in the return path after reflection. Also in this return path, the probability of the absorption of light in the light-receiving layer is the same as that in the outgoing path. In the present embodiment, a certain proportion of the region (limited region) of the pixel electrode 11 is constituted by the smooth metal surface K. With this structure, light does not pass only in one way of the outgoing path, but can obtain a chance to be received by the light-receiving layer 3 also in the return path after reflection by using the metal surface K as a reflection surface. As a result, the light-receiving sensitivity can be improved.

The reflection surface or the metal surface K on the back surface of the pixel electrode 11 is preferably provided in a region including the center of the pixel electrode 11. The region J having the rough surface in which ohmic contact is formed is preferably provided in a peripheral portion of the pixel electrode 11. The pixel electrode 11 is disposed at the center of a pixel region in plan view. Accordingly, when the metal surface K is located at the center of the pixel electrode 11, the reflected light can pass through the light-receiving layer 3 with a low proportion of loss of the reflected light. In addition, since the peripheral portion of the pixel electrode 11 has a sufficient length and thus a desired area is easily provided, the electrical resistance can be easily decreased.

The SiN film and the like, which are the materials used for the reaction-preventing film 8, are inexpensive materials that are commonly used. In addition, the formation of the reaction-preventing film 8 or the formation of the metal surface K does not require a significant change in a step or significant addition of a step, as described in a production method below. Thus, the sensitivity can be easily improved with good cost efficiency.

Next, the reflection surface formed by the metal surface K will be described in detail when the light-receiving layer 3 of the light-receiving element 10 in the present embodiment has a type-II (GaAsSb/InGaAs) MQW structure.

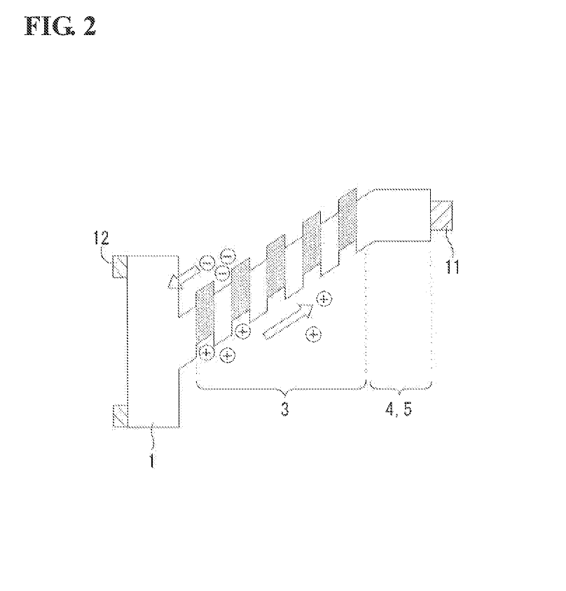

Light incident on the light-receiving element 10 is absorbed in the light-receiving layer 3. An electron-hole pair is then generated, and a current is output as a photocurrent. In order to increase the sensitivity, it is necessary to increase the thickness of the light-receiving layer 3 so as to increase the chance to be absorbed. In particular, when the light-receiving layer 3 has a type-II MQW structure, for example, the (GaAsSb/InGaAs) MQW structure described above, the light absorption probability based on the transition of type-II is low as described above. Therefore, in order to obtain a high sensitivity, it is necessary that the number of pairs of layers in the MQW structure be 200 or more. However, when the thickness of the light-receiving layer 3 is increased or the number of pairs of layers in the MQW structure is increased, the crystal quality tends to degrade and it becomes difficult to grow the MQW structure with a high quality. Furthermore, as shown in FIG. 2, when the light-receiving layer 3 has an MQW structure, electrons and holes generated by light absorption must pass through a rising and falling potential barrier of an MQW structure until the electrons and the holes reach respective electrodes. When the number of pairs of layers in the MQW structure is increased, the number of the rising and falling potential barriers to be passed through is increased. Accordingly, annihilation of the electrons and the holes occurs. These electrons and the holes which are annihilated in passing through the rising and falling potential barriers of the MQW structure do not contribute to the sensitivity.

This point will be described in more detail with reference to FIG. 2. Light incident from a back surface of an InP substrate 1 is absorbed in a light-receiving layer 3 to generate electrons (denoted by minus symbols in FIG. 2) and holes (denoted by plus symbols in FIG. 2). Holes generated in a portion near the InP substrate 1 must pass through rising and falling potential barrier of the MQW structure until the holes reach a pixel electrode (p-side electrode) 11, and many of the holes are annihilated in passing through the rising and falling potential barriers of the MQW structure. In particular, since holes have an effective mass larger than that of electrons, the probability in which holes cannot pass through the MQW structure is high. In order to prevent holes from annihilation in the MQW structure, a smaller number of pairs of layers in the MQW structure is more advantageous. However, when the number of pairs is small, light absorption in the light-receiving layer 3 is decreased, thereby decreasing the sensitivity.

To address this problem, in the present embodiment, even when the light-receiving layer 3 has a certain small thickness, light that has passed without having been absorbed is reflected by the smooth metal surface K, and returned to the light-receiving layer 3. Here, the metal surface K is formed on the back surface of the pixel electrode 11 opposite to the light-incident surface. With this structure, the reflected light is returned to the light-receiving layer 3 and can obtain a chance to be received by the light-receiving layer 3 again. That is, the light does not pass only in one way of the outgoing path, but obtains a chance to be received in the return path. Thus, the sensitivity can be increased.

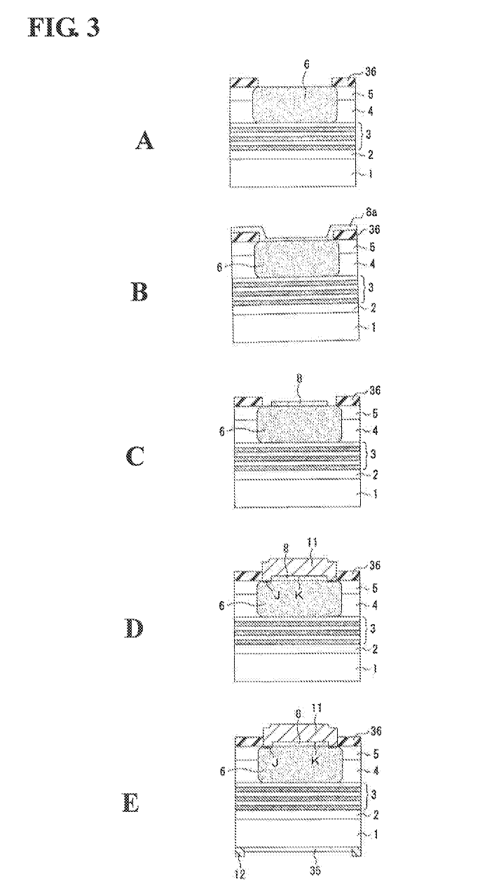

Next, a production method will be described with reference to part A of FIG. 3 to part E of FIG. 3. Part A of FIG. 3 is a view showing a step of forming a p-type region 6 by selectively diffusing Zn, which is a p-type impurity, through an opening of a selective diffusion mask pattern 36 in order to form a p-n junction in the production of the planar type p-i-n photodiode shown in FIG. 1A. The selective diffusion mask pattern 36 is composed of for example, SiN and is formed by a plasma chemical vapor deposition (CVD) method so as to have a thickness of about 100 nm, for example.

The term “p-n junction” described above should be broadly interpreted as follows. In the light-receiving layer 3, when a region on a side opposite to a surface from which an impurity element is introduced by selective diffusion is an intrinsic region (referred to as “i-region”), a junction formed between this i-region and the impurity region formed by the selective diffusion is also defined as the p-n junction. Here, the intrinsic region (i-region) is defined as an intrinsic semiconductor region in which any impurity does not doped intentionally. Therefore, the intrinsic region (i-region) has an impurity concentration low enough. That is, the p-n junction may include a p-i junction, an n-i junction, or the like. Furthermore, the p-i junction having a very low p concentration and the n-i junction having a very low n concentration are also included in the p-n junction.

The light-receiving layer 3 has a type-II (GaAsSb/InGaAs) MQW structure. The thickness of a GaAsSb layer is 5 nm, and the thickness of an InGaAs layer is 5 nm. The total number of pairs of GaAsSb layers and InGaAs layers is 145. In the embodiment, the number of pairs of layers is made smaller than the number of pairs (200 or more) of layers in MQW structure of the conventional light-receiving elements, as described above. As a result, a good crystal quality may be obtained and the proportion of holes that are annihilated in the MQW structure may be decreased. Consequently, the sensitivity of the light-receiving element may be increased as a whole while the optimal thickness is set to be a smaller thickness. In addition, this structure is advantageous in that, for example, the number of steps is reduced in the production process.

Next, as shown in part B of FIG. 3, a layer 8a of a reaction-preventing film is deposited by a plasma CVD method, for example. The layer 8a is formed of a SiN layer and has a thickness of about 20 nm. Although the reaction-preventing film (layer 8a) is composed of the same material as the selective diffusion mask pattern 36, the thickness of the reaction-preventing film (layer 8a) is smaller than that of the selective diffusion mask pattern 36. For example, the thickness of the reaction-preventing film (layer 8a) is about ⅕ of the thickness of the selective diffusion mask pattern 36. In order to form the reaction-preventing film 8, a resist pattern covering portion as a resist mask (not shown) is formed on the layer 8a so as to overlap with a region for forming the reaction-preventing film 8. As shown in part C of FIG. 3, a residual portion of the layer 8a is removed by selective etching using the resist pattern covering portion (resist mask) so as to leave a portion which becomes the reaction-preventing film 8. In the step of the selective diffusion of Zn, the condition of heating at 480° C. to 520° C. for 30 to 40 minutes is essential. When the SiN film (selective diffusion mask pattern 36) is heated at substantially the same temperature as a temperature in the step of the selective diffusion of Zn, the SiN film is not easily etched. On the other hand, the layer 8a formed of a SiN film is deposited after heat treatment for selective diffusion. Accordingly, when the layer 8a is etched by, for example, buffered hydrofluoric acid, the selective diffusion mask pattern 36 is not etched and only the layer 8a of the reaction-preventing film is etched. In this step, the reaction-preventing film 8 is formed on a surface of the p-type region 6 of the contact layer 5.

Subsequently, as shown in part D of FIG. 3, in order to form a pixel electrode 11, AuZn is deposited by using an electron-beam evaporation method. Heat treatment is then performed at 390° C. for one minute in a nitrogen atmosphere in order to form ohmic contact with the p-type region 6 of the contact layer 5. This heat treatment forms a metal surface K on a back surface of the pixel electrode 11, the back surface being in contact with the reaction-preventing film 8. In a region where the pixel electrode 11 contacts the p-type region 6 of the contact layer 5, a chemical reaction proceeds and a region J having a rough surface is formed. Accordingly, ohmic contact is formed between the pixel electrode 11 and the p-type region 6 of the contact layer 5. Subsequently, as shown in part E of FIG. 3, an AR film 35 composed of, for example, SiON is formed by a plasma CVD method on a back surface of an InP substrate 1, the back surface functioning as a light-incident surface. Furthermore, a ground electrode 12 is formed by depositing AuGeNi on a peripheral portion of the back surface of the InP substrate 1. In the embodiment, a ground electrode 12 is an n-side electrode and forms a pair with the pixel electrode 11 which is a p-side electrode. Subsequently, in order to form ohmic contact of the ground electrode 12 with the InP substrate 1, heat treatment is performed at 340° C. for one minute. The selective diffusion mask pattern 36 is left in this state and used as a protective film or a passivation film.

To be exact, the region J having the rough surface formed on the back surface of the pixel electrode 11 is also affected by the thermal history of the heat treatment in the step of forming ohmic contact of the ground electrode 12 with the InP substrate 1. However, the heat treatment for forming ohmic contact of the pixel electrode 11 is performed at 390° C., which is about 50° C., higher than the temperature of the heat treatment for the ground electrode 12. Thus, the region J having the rough surface is substantially formed by the heat treatment for forming ohmic contact of the pixel electrode 11.

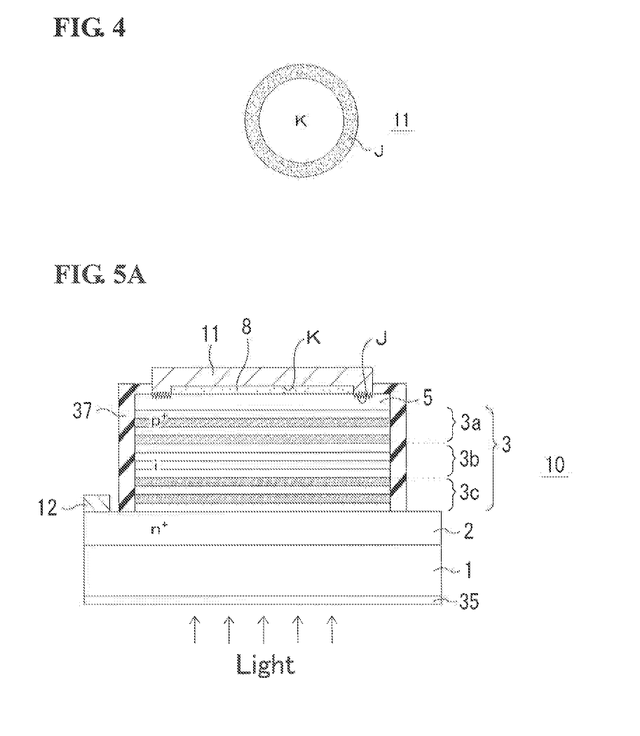

Through the above production process, as shown in FIG. 4, the region J having the rough surface is formed on a peripheral portion of the back surface of the pixel electrode 11 so as to form ohmic contact. In addition, a smooth or substantially smooth metal surface K is formed on a central portion of the back surface of the pixel electrode 11, the central portion being surrounded by the region J.

### Embodiment 2

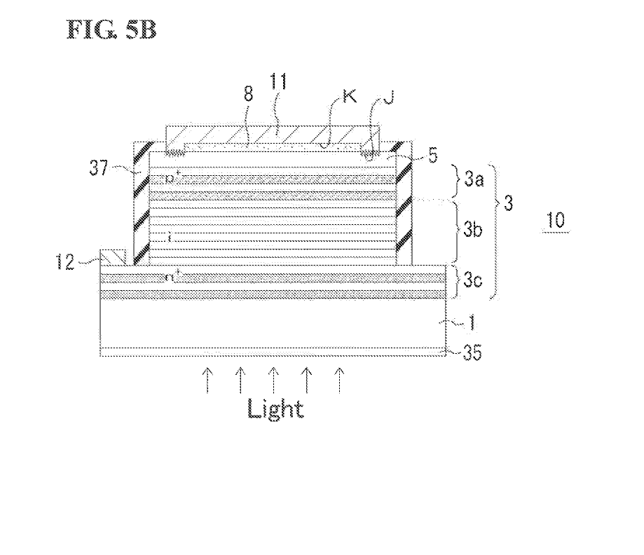

FIGS. 5A and 5B show a light-receiving element 10 according to Embodiment 2 of the present invention. A reaction-preventing film 8 is provided on a lower portion of a pixel electrode 11. Embodiment 2 is common to Embodiment 1 in that the sensitivity is improved by using a smooth or substantially smooth metal surface K as a reflection surface while ohmic contact is formed in a region J having a rough surface. As a result, an optimal number of pairs of layers for improving the sensitivity may be selected while the number of pairs of layers in a light-receiving layer 3 having a type-II (GaAsSb/InGaAs) MQW structure is relatively small.

In the present embodiment, the light-receiving element 10 has a mesa structure rather than a planar-type structure, and the structure of the light-receiving layer is different from that of the planar-type structure in the embodiment 1. In the mesa structure, it is important that a side surface of the mesa structure and a contact layer 5 around the pixel electrode 11 be covered with a passivation film 37 because exposure of a p-n junction on the side surface of the mesa structure may cause a leak current.

The structure of the light-receiving layer in the present embodiment is as follows.
<Semiconductor substrate 1:>: Semi-insulating InP substrate doped with Fe
<Buffer layer 2> (n⁺-type): When a lower layer 3c of the light-receiving layer is provided, a buffer layer 2 may be provided or may not be provided. When a buffer layer 2 is provided, the buffer layer 2 is composed of InGaAs or InP and has a thickness of 0.5 μm.
<Light-receiving layer 3>: Lower layer 3c (n⁺-type) of light-receiving layer: (GaAsSb (5 nm)/InGaAs (5 nm)) MQW structure, 30 pairs

FIG. 5A shows a structure where both a lower layer 3c of the light-receiving layer and a buffer layer 2 are provided. FIG. 5B shows a structure where only a lower layer 3c of the light-receiving layer is provided and a buffer layer 2 is not provided. In FIG. 5A, the lower layer 3c of the light-receiving layer may not be provided and the light-receiving layer 3 may include only a middle layer 3b and an upper layer 3a.

Middle layer 3b (i-type) of light-receiving layer: (GaAsSb (5 nm)/InGaAs (5 nm)) MQW structure, 90 pairs

Upper layer 3a (p⁺-type) of light-receiving layer: (GaAsSb (5 nm)/InGaAs (5 nm)) MQW structure, 25 pairs
<Contact layer 5>: (p⁺-type): InGaAs or InP. The thickness is 0.6 μm in each case.
<Ground electrode 12>: Since the semiconductor substrate 1 is made of semi-insulating InP doped with Fe, a ground electrode 12 which is an n-side electrode is provided on the n⁺-type buffer layer 2 or the lower layer 3c of the light-receiving layer. The ground electrode 12 is in ohmic contact with the n⁺-type buffer layer 2 or the lower layer 3c.
<Passivation film 37>: A passivation film 37 is composed of SiO₂ and has a thickness of 0.3 μm. The passivation film 37 is firmed by a plasma CVD method.

An AR film 35 is composed of SiON. The materials of the pixel electrode 11 and the ground electrode 12 are the same as those in Embodiment 1.

The shorter the distance between the pixel electrode 11 and the light-receiving layer 3, the more easily light reflected by the pixel electrode 11 is returned to the light-receiving layer 3 with a low loss. The distance between the pixel electrode 11 and the light-receiving layer 3 in a mesa structure may be made shorter than that in a planar-type structure in which pixels are separated from each other by using selective diffusion. Accordingly, the mesa structure is more preferable from the viewpoint that reflected light can be used with a low loss.

### Embodiment 3

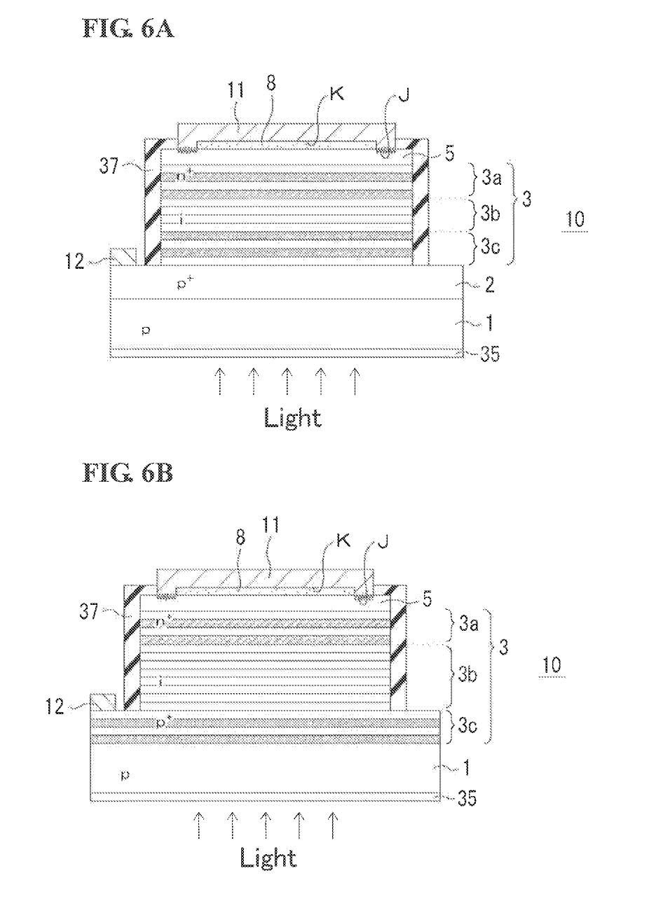

FIGS. 6A and 6B show a light-receiving element 10 according to Embodiment 3 of the present invention. Embodiment 3 is common to Embodiments 1 and 2 in that a reaction-preventing film 8 is provided on a lower portion of a pixel electrode 11 and the sensitivity is improved by using a smooth or substantially smooth metal surface K as a reflection surface while ohmic contact is formed in a region J having a rough surface. The present embodiment is common to Embodiment 2 in that the light-receiving element 10 has a mesa structure rather than a planar-type structure. In the present embodiment, the materials of an MQW structure of a light-receiving layer 3 are different.

The structure of the light-receiving layer in the present embodiment is as follows.

<Semiconductor substrate 1>: Non-doped GaSb substrate (p-type)

The GaSb substrate is not intentionally doped with an impurity, but has a p-type conductivity.
<Buffer layer 2> (p⁺-type): When a lower layer 3c of the light-receiving layer is provided, a buffer layer 2 may be provided or may not be provided. When a buffer layer 2 is provided, the buffer layer 2 is formed of a GaSb layer and has a thickness of 0.5 μm.
<Light-receiving layer 3>:

Lower layer 3c (p⁺-type) of light-receiving layer: (InAs (3.6 nm)/GaSb (2.1 nm)) MQW structure, 30 pairs

FIG. 6A shows a structure where both a lower layer 3c of the light-receiving layer and a buffer layer 2 are provided. FIG. 6B shows a structure where only a lower layer 3c of the light-receiving layer is provided and a buffer layer 2 is not provided. In FIG. 6A, the lower layer 3c of the light-receiving layer may not be provided and the light-receiving layer 3 may include only a middle layer 3b of the light-receiving layer and an upper layer 3a of the light-receiving layer,

Middle layer 3b (i-type) of light-receiving layer: (InAs (3.6 nm)/GaSb (2.1 nm)) MQW structure, 190 pairs

Upper layer 3a (n⁺-type) of light-receiving layer: (InAs (3.6 nm)/GaSb (2.1 nm)) MQW structure, 30 pairs
<Contact layer 5>: (n⁺-type): InAs layer, thickness 0.02 μm
<Pixel electrode 11>: Ti/Pt films are deposited and heat treatment is then performed at 200° C. for one minute. Thus, ohmic contact is formed in a region J having a rough surface of a peripheral portion. The pixel electrode 11 is an n-side electrode.
<Ground electrode 12>: A ground electrode 12 which is a p-side electrode is provided on the p⁺-type buffer layer 2 or the lower layer 3c of the light-receiving layer. The ground electrode 12 is in ohmic contact with the p⁺-type buffer layer 2 or the lower layer 3c. Ti/Pt films are deposited and heat treatment is then performed at 200° C. for one minute. Thus, ohmic contact is formed.

An AR film provided on a back surface of the substrate 1 is composed of diamond-like carbon (DLC).

In the present embodiment, a GaSb substrate 1 is used, and a light-receiving layer 3 has a type-II (GaSb/InAs) MQW structure. The type-II (GaSb/InAs) MQW structure has a sensitivity in a longer wavelength band as compared with the type-II (GaAsSb/InGaAs) of Embodiments 1 and 2, and can receive light having a wavelength in a mid-infrared wavelength band. In this case, a high sensitivity can be secured to light in the mid-infrared wavelength band by the metal surface K due to the reaction-preventing film 8 provided under the pixel electrode 11, the metal surface K having been described in detail in Embodiment 1.

### Embodiment 4

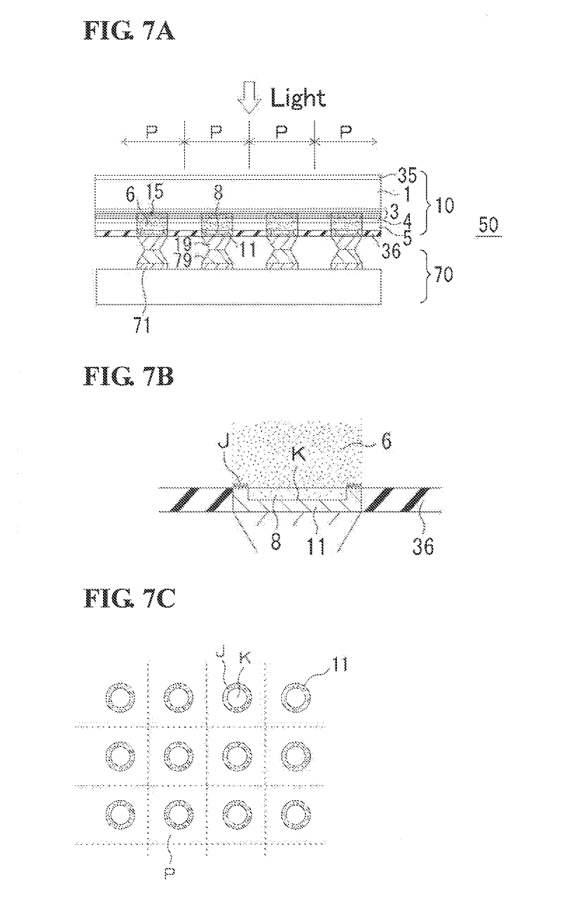

FIGS. 7A, 7B, and 7C show an optical device 50 according to Embodiment 4 of the present invention. FIG. 7A is a cross-sectional view, FIG. 7B is a partially enlarged view, and FIG. 7C is a plan view of a back surface of pixel electrodes 11 in a light-receiving element 10. In the light-receiving element 10 of the present embodiment, a plurality of pixels P are arranged in an array manner. The above-described operation of reflection by the metal surface K is reliably achieved in the light-receiving element 10 even when a plurality of pixels P are (one-dimensionally or two dimensionally) arranged in this manner.

In Embodiment 1 to 3, examples of the cases where a single pixel is provided are shown in the drawings. However, it may be interpreted that a plurality of pixels are arranged in Embodiments 1 to 3, as shown in FIG. 7A.

The optical device 50 includes a light-receiving element 10 and a read-out integrated circuit (ROIC) 70. In each pixel P, a pixel electrode 11 is connected to a read-out electrode 71 of the ROIC 70 with a bump 19 and a bump 79 therebetween. A stacked layer structure in the light-receiving element 10 is the same as that of the light-receiving element 10 of Embodiment 1 shown in FIG. 1. A back surface of an InP substrate 1 functions as a light-incident surface.

As shown in FIG. 7B, a reaction-preventing film 8 is disposed in a limited region between a pixel electrode 11 and a p-type region 6 of a contact layer 5, and a smooth or substantially smooth metal surface K is formed in the region. A region J having a rough surface is located in a circumferential region so as to surround the metal surface K. While ohmic contact of the pixel electrode 11 with the contact layer 5 is formed at the region J having the rough surface, light that has once passed through a light-receiving layer 3 is reflected by the metal surface K, and is then returned to the light-receiving layer 3. Therefore, the reflected light from the metal surface K is received by the light-receiving layer 3, again. Thus, the sensitivity of each pixel P in the light-receiving element 10 can be enhanced.

FIG. 7C is a plan view of showing a back surface of pixel electrodes 11 when pixels P are two-dimensionally arrayed. A metal surface K that improves the sensitivity in each pixel P and a region J having a rough surface to enhance the formation of ohmic contact in each pixel P are formed by simply changing a production process. An important point is that the region having the rough surface that enhances the formation of ohmic contact is reliably formed. When a pitch of the pixels P is about 30 μm, the region J having a predetermined area is reliably formed within the range of the current accuracy of dimension.

### Other Embodiments

Only a p-i-n photodiode has been described as a light-receiving element. Alternatively, a light-receiving element may include a light-receiving layer having a so-called n-B-n structure in which an insertion layer having a bottom of the conduction band higher than a bottom of the conduction band of the light-receiving layer is provided in the light-receiving layer. That is, even when a light-receiving element includes a light-receiving layer having the n-B-n structure, the effects of the metal surface K and the region J having a rough surface in the present embodiment can be achieved without problems. Accordingly, alight-receiving element may include a light-receiving layer having the n-B-n structure.

Only a type-II MQW structure has been described as an example of the structure of alight-receiving layer. However, the structure of the light-receiving layer is not limited to an MQW structure. A light-receiving layer may be composed of a single layer.

Embodiments and Examples of the present invention have been described above. The embodiments and Examples of the present invention disclosed above are only illustrative, and the scope of the present invention is not limited to these embodiments of the invention. It is to be understood that the scope of the present invention is defined by the description of Claims and includes equivalence of the description in Claims and all modifications within the scope of Claims.

### INDUSTRIAL APPLICABILITY

According to a light-receiving element, etc. of the present invention, by arranging a reaction-preventing film in a limited region under a pixel electrode, an improvement in the sensitivity due to a reflection surface can be achieved while ohmic contact of the pixel electrode is secured. In a production method for forming this structure, a particularly significant change in a step is not necessary. In addition, existing materials are used in this method. As a result of the improvement in the sensitivity due to the reflection surface, for example, when a light-receiving layer has a type-II MQW structure, the number of pairs of layers in the MQW structure can be made smaller than the number of pairs of layers in a MQW structure of the conventional light-receiving elements. Consequently, a higher light-receiving sensitivity can be obtained, and a dark current can also be reduced by an improvement in the crystal quality.

1. A light-receiving element including a pixel comprising:
a semiconductor substrate having a back surface including a light-incident surface;
a light-receiving layer for receiving light, the light-receiving layer being disposed on the semiconductor substrate;
a contact layer disposed on the light-receiving layer;
a reaction-preventing film disposed on the contact layer, the reaction-preventing film having an opening; and
a pixel electrode disposed on the reaction-preventing film,
wherein the pixel electrode is formed in the opening, and
the pixel electrode is in ohmic contact with the contact layer through the opening.

2. The light-receiving element according to claim 1, wherein the pixel electrode is in contact with the reaction-preventing film at a region including a center of the pixel electrode, and
the opening of the reaction-preventing film is located at a peripheral portion of the reaction-preventing film.

3. The light-receiving element according to claim 1, further comprising a protective film that covers at least a surface of the contact layer around the pixel electrode,
wherein the opening is disposed between the reaction-preventing film and the protective film on the contact layer, and
the reaction-preventing film has a thickness smaller than a thickness of the protective film.

4. The light-receiving element according to claim 1, wherein the reaction-preventing film is at least one of a silicon nitride (SiN) film, a silicon oxynitride (SiON) film, and a silicon oxide (SiO₂) film.

5. The light-receiving element according to claim 1, wherein the light-receiving layer includes a p-n junction, therein.

6. The light-receiving element according to claim 1, wherein the light-receiving layer has a type-II multi-quantum well (MQW) structure.

7. A method for manufacturing a light-receiving element including a pixel, the method comprising the steps of:
forming a light-receiving layer on a semiconductor substrate;
forming a contact layer on the light-receiving layer;
forming a reaction-preventing film on the contact layer, the reaction-preventing film has a first opening at a peripheral portion of the reaction-preventing film, the contact layer being exposed through the first opening;
forming a pixel electrode on the reaction-preventing film and in the first opening of the reaction-preventing film, the pixel electrode being in contact with the contact layer through the first opening; and
conducting heat treatment to the pixel electrode so that the pixel electrode in the first opening and the contact layer chemically react each other to establish ohmic contact.

8. The method for manufacturing a light-receiving element according to claim 7, after the step of forming the contact layer, further includes a step of forming a protective film on the contact layer other than a region on which the pixel electrode is to be provided,
wherein the step of forming the reaction-preventing film includes the steps of:
forming an insulating layer on the protective film and on the contact layer;
forming a mask on the insulating layer, the mask having a pattern including the first opening of the reaction-preventing film; and
etching the insulating layer so as to form the reaction-preventing film using the mask.

9. The method for manufacturing a light-receiving element according to claim 7, further includes steps of:
forming on the contact layer between the step of forming the contact layer and the step of forming the reaction-preventing film, the selective diffusion mask having a pattern including a second opening; and
selectively diffusing an impurity through the second opening using the selective diffusion mask at a predetermined temperature,
wherein the step of forming the reaction-preventing film includes the steps of:
forming an insulating layer on the selective diffusion mask and on the contact layer exposed through the second opening after selectively diffusing the impurity;
forming a mask on the insulating layer, the mask having a pattern including the first opening of the reaction-preventing film; and
etching the insulating layer so as to form the reaction-preventing film using the mask.

10. The method for manufacturing a light-receiving element according to claim 9, wherein the selective diffusion mask is left on the contact layer without removing after selectively diffusing the impurity, and
the selective diffusion mask functions as a protective film.

11. The method for manufacturing a light-receiving element according to claim 7, further includes the steps of:
forming a mesa structure defined by a groove on the semiconductor substrate between the step of forming the contact layer and the step of the reaction-preventing film, the mesa structure including the light-receiving layer and the contact layer formed on the light-receiving layer,
forming a protective layer on the contact layer and on a side surface of the mesa structure, the protective layer has a third opening,
wherein the step of forming the reaction-preventing film includes the steps of:
forming an insulating layer on an entire surface is of the semiconductor substrate;
forming a mask on the insulating layer, the mask having a pattern including the first opening of the reaction-preventing film; and
etching the insulating layer so as to form the reaction-preventing film in the third opening of the protective layer using the mask.
